(19) United States
(12) Patent Application Publication
(10) Pub. No.: US 2023/0309229 A1
(43) Pub. Date: Sep. 28, 2023

(54) ELECTRONIC COMPONENT

(71) Applicant: TDK CORPORATION, Tokyo (JP)

(72) Inventors: Takeshi OOHASHI, Tokyo (JP); Yukio MITAKE, Tokyo (JP); Daiki KUSUNOKI, Tokyo (JP)

(73) Assignee: TDK CORPORATION, Tokyo (JP)

(21) Appl. No.: 18/073,670

(22) Filed: Dec. 2, 2022

(30) Foreign Application Priority Data
Mar. 28, 2022 (JP) 2022-051977

(51) Int. Cl. H05K 1/16; H05K 1/11

(52) U.S. Cl. CPC H05K 1/165; H05K 1/162; H05K 1/111; H05K 2201/09545; H05K 2201/10522; H05K 2201/10931; H05K 2201/10818

(57) ABSTRACT

An electronic component includes an insulator and an inductor pattern and a capacitor pattern which are arranged in the insulator. The inductor pattern and the capacitor pattern are electrically connected between one end and the other end of the first inductor pattern.

### TECHNICAL FIELD

The present disclosure relates to an electronic component.

### BACKGROUND

For example, an electronic component described in Patent Document 1 (Japanese Unexamined Patent Publication No. 2013-143675) is known as an electronic component according to the related art. The electronic component described in Patent Document 1 includes an element assembly and an inductor pattern and a capacitor pattern which are disposed in the element assembly.

### SUMMARY

In the electronic component according to the related art, a capacitor pattern is connected to an end of an inductor pattern via a through-hole conductor. In this configuration, since the capacitor pattern has to be disposed at a position which is connected to the end of the inductor pattern via the through-hole conductor, arrangement of the capacitor pattern is restricted.

An objective of an aspect of the present disclosure is to provide an electronic component that can achieve improvement in a degree of freedom in design associated with arrangement of capacitor patterns.

According to an aspect of the present disclosure, there is provided an electronic component including an element assembly and a first inductor pattern and a first capacitor pattern arranged in the element assembly, wherein the first inductor pattern and the first capacitor pattern are electrically connected between one end and the other end of the first inductor pattern.

In the electronic component according to the aspect of the present disclosure, the first inductor pattern and the first capacitor pattern are electrically connected between one end and the other end of the first inductor pattern. In this way, in the electronic component, one end or the other end of the first inductor pattern and the first capacitor pattern are not electrically connected, but the first inductor pattern and the first capacitor pattern are electrically connected at a position between the one end and the other end of the first inductor pattern. Accordingly, in the electronic component, arrangement of the first capacitor pattern is not restricted in a relationship with a position of the one end or the other end of the first inductor pattern. As a result, it is possible to achieve improvement in a degree of freedom in design associated with arrangement of the capacitor patterns in the electronic component.

In an embodiment, a first connection portion may be provided between the one end and the other end of the first inductor pattern, and the first connection portion may be electrically connected to the first capacitor pattern. With this configuration, arrangement of the first capacitor pattern can be changed by changing the position of the first connection portion. Accordingly, it is possible to achieve improvement in a degree of freedom in design associated with arrangement of capacitor patterns.

In an embodiment, the element assembly may include a pair of end faces facing each other in a first direction, a pair of principal faces facing each other in a second direction, and a pair of side faces facing each other in a third direction, the electronic component may further include a second inductor pattern arranged in the element assembly, and the first inductor pattern and the second inductor pattern may be arranged in parallel in the first direction when seen in the second direction. In this way, in the configuration in which a plurality of inductor patterns are arranged in parallel, arrangement of the capacitor patterns may be restricted. Particularly, when it is intended to decrease the size of the electronic component, a space for arrangement of the capacitor patterns is restricted and thus a degree of freedom in arrangement of the capacitor patterns decreases. Accordingly, the configuration in which the first connection portion and the first capacitor pattern are connected is useful for the configuration in which a plurality of inductor patterns are arranged in parallel.

In an embodiment, the electronic component may further include a plurality of terminal electrodes arranged in the element assembly, two terminal electrodes out of the plurality of terminal electrodes may be arranged separately in the third direction when seen in the second direction, and the first connection portion may be arranged outside of an area between the two terminal electrodes arranged separately in the third direction. In the configuration in which the first inductor pattern and the second inductor pattern are arranged in parallel in the first direction, when the first connection portion is arranged in an area between two terminal electrodes arranged separately in the third direction, a diameter of the first inductor pattern decreases and desired characteristics are hard to obtain. Therefore, it is possible to secure the diameter of the first inductor pattern by arranging the first connection portion outside of the area between two terminal electrodes arranged separately in the third direction.

In an embodiment, the electronic component may further include a third inductor pattern and a third capacitor pattern, the first inductor pattern, the second inductor pattern, and the third inductor pattern may be arranged in parallel in the first direction when seen in the second direction, a third connection portion may be provided between one end and the other end of the third inductor pattern, and the third connection portion may be electrically connected to the third capacitor pattern. In this way, in the configuration in which a plurality of inductor patterns are arranged in parallel, arrangement of the capacitor patterns may be restricted. Particularly, when it is intended to decrease the size of the electronic component, a space for arrangement of the capacitor patterns is restricted and thus a degree of freedom in arrangement of the capacitor patterns decreases. Accordingly, the configuration in which the first connection portion and the first capacitor pattern are connected and the third connection portion and the third capacitor pattern are connected is useful for the configuration in which a plurality of inductor patterns are arranged in parallel.

According to an aspect of the present disclosure, it is possible to achieve improvement in a degree of freedom in design associated with arrangement of capacitor patterns.

### BRIEF DESCRIPTION OF THE DRAWINGS

FIG. 1 is a perspective view illustrating an electronic component according to an embodiment.

FIG. 2 is a view of the electronic component illustrated in FIG. 1 when seen from an insulator side.

FIG. 3 is a view of the electronic component illustrated in FIG. 1 when seen from a substrate side.

FIG. 4A is a side view of the electronic component and FIG. 4B is a sectional view of the electronic component.

FIGS. 5A, 5B, 5C, 5D, 5E, 5F, 5G, and 5H are diagrams illustrating conductor patterns constituting an LC filter unit.

FIG. 6A is a sectional view taken along line VI-VI in FIG. 2 and FIG. 6B is a partially enlarged view of FIG. 6A.

FIG. 7 is an equivalent circuit diagram of the electronic component.

### DETAILED DESCRIPTION

Hereinafter, an exemplary embodiment of the present disclosure will be described in detail with reference to the accompanying drawings. In description with reference to the drawings, the same or corresponding elements will be referred to by the same reference signs and description thereof will not be repeated.

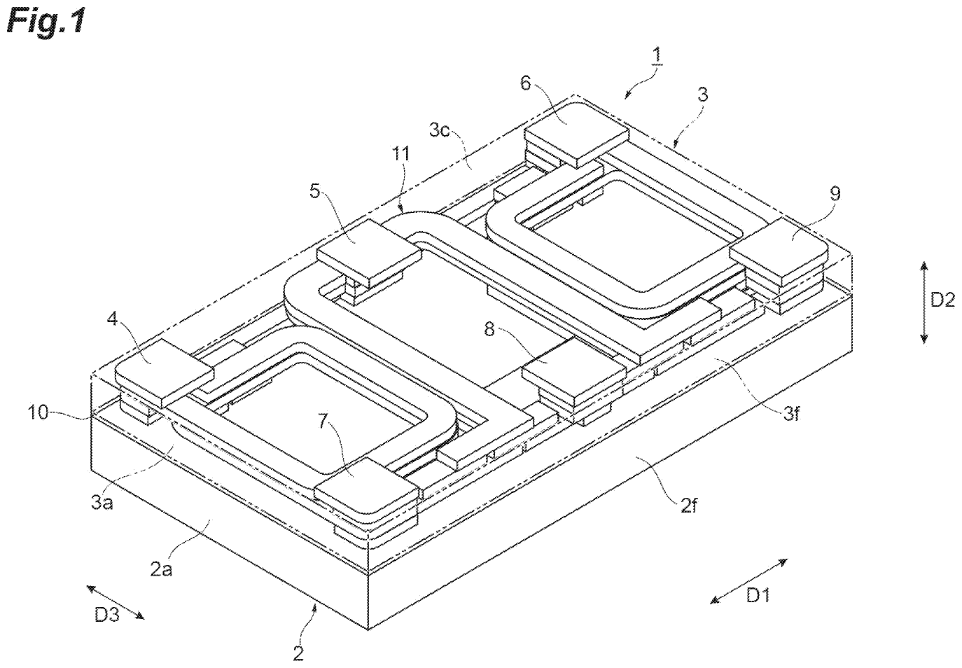

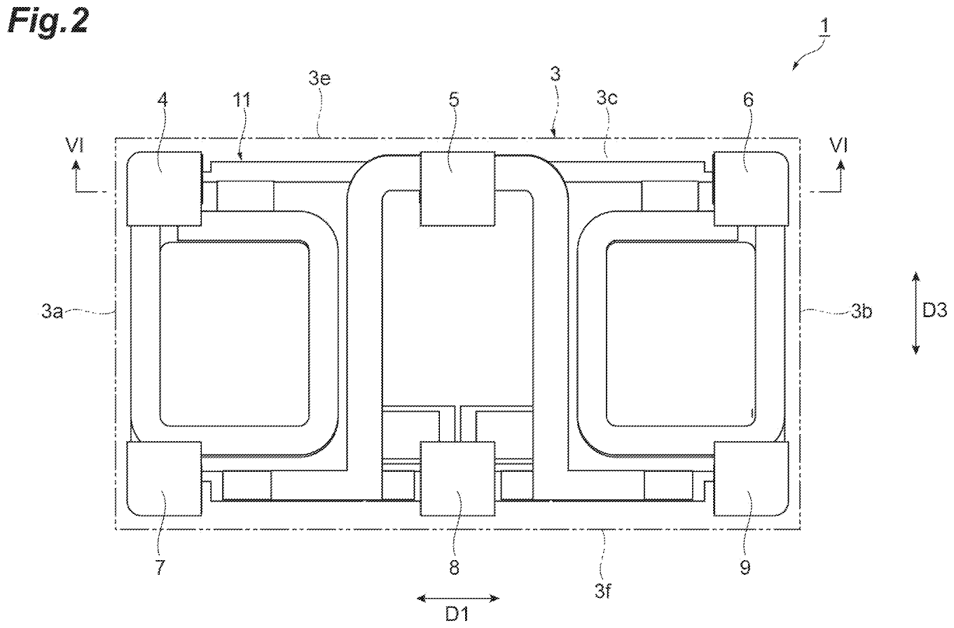

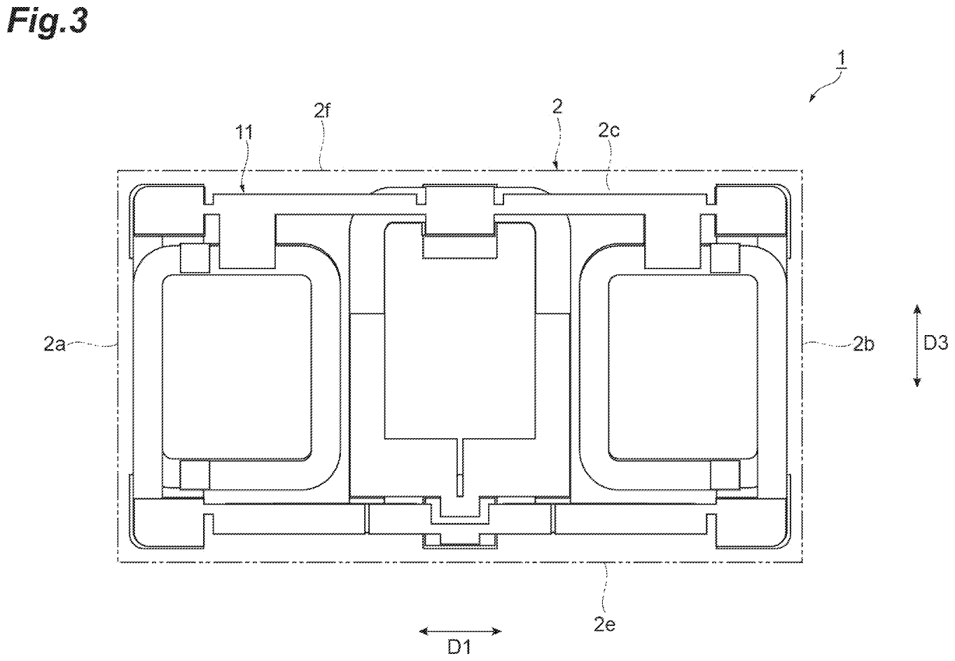

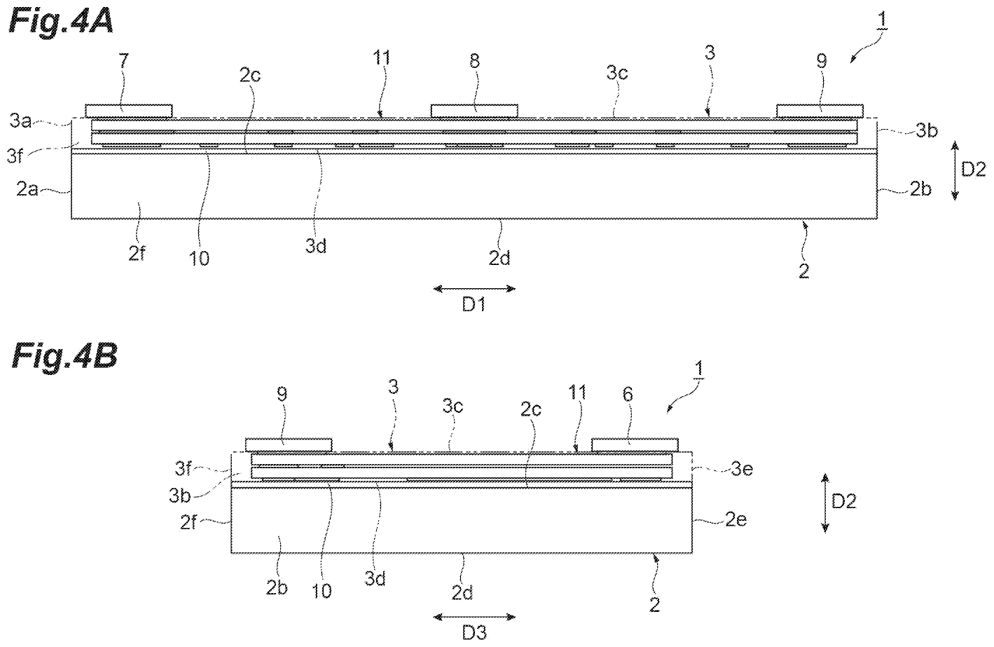

FIG. 1 is a perspective view illustrating an electronic component according to an embodiment. FIG. 2 is a view of the electronic component illustrated in FIG. 1 when seen from an insulator side. FIG. 3 is a view of the electronic component illustrated in FIG. 1 when seen from a substrate side. FIG. 4A is a side view of the electronic component and FIG. 4B is a sectional view of the electronic component.

The electronic component 1 illustrated in FIG. 1 is an LC filter. The electronic component 1 is a so-called thin-film LC filter. As illustrated in FIGS. 1 and 2, the electronic component 1 includes a substrate 2, an insulator (an element assembly) 3, and a first terminal electrode 4, a second terminal electrode 5, a third terminal electrode 6, a fourth terminal electrode 7, a fifth terminal electrode 8, and a sixth terminal electrode 9 which are disposed in the insulator 3.

The substrate 2 has a rectangular parallelepiped shape. The rectangular parallelepiped shape includes a rectangular parallelepiped shape in which corners and edges are chamfered and a rectangular parallelepiped shape in which corners and edges are rounded. The substrate 2 includes a pair of end faces 2a and 2b facing each other, a pair of principal faces 2c and 2d facing each other, and a pair of side faces 2e and 2f facing each other as outer surfaces thereof.

The opposing direction in which the pair of end faces 2a and 2b face each other is defined as a first direction D1. The opposing direction in which the pair of principal faces 2c and 2d face each other is defined as a second direction D2. The opposing direction in which the pair of side faces 2e and 2f face each other is defined as a third direction D3. In this embodiment, the first direction D1 is defined as a length direction of the substrate 2. The second direction D2 is defined as a height direction of the substrate 2 and is perpendicular to the first direction D1. The third direction D3 is defined as a width direction of the substrate 2 and is perpendicular to the first direction D1 and the second direction D2.

The pair of end faces 2a and 2b extend in the second direction D2 such that the pair of principal faces 2c and 2d are connected. The pair of end faces 2a and 2b also extend in the third direction D3. The pair of side faces 2e and 2f extend in the second direction D2 such that the pair of principal faces 2c and 2d are connected. The pair of side faces 2e and 2f also extend in the first direction D1.

The substrate 2 is formed of a material that is chemically and thermally stable, has less stress caused therein, and can keep smoothness of a surface thereof. The material is not particularly limited and single crystalline silicon, alumina, sapphire, aluminum nitride, MgO single crystal, SrTiO₃ single crystal, surface-oxidized silicon, glass, quartz, ferrite, or the like can be used.

The insulator 3 has a rectangular parallelepiped shape. The insulator 3 includes a pair of end faces 3a and 3b facing each other, a pair of principal faces 3c and 3d facing each other, and a pair of side faces 3e and 3f facing each other as outer surfaces thereof. The pair of end faces 3a and 3b face each other in the first direction D1. The pair of principal faces 3c and 3d face each other in the second direction D2. The pair of side faces 3e and 3f face each other in the third direction D3.

The pair of end faces 3a and 3b extend in the second direction D2 such that the pair of principal faces 3c and 3d are connected. The pair of end faces 3a and 3b also extend in the third direction D3. The pair of side faces 3e and 3f extend in the second direction D2 such that the pair of principal faces 3c and 3d are connected. The pair of side faces 3e and 3f also extend in the first direction D1. The dimension in the first direction D1 of the insulator 3 is equivalent to the dimension in the first direction D1 of the substrate 2. The dimension in the third direction D3 of the insulator 3 is equivalent to the dimension in the third direction D3 of the substrate 2.

“Equivalence” in this embodiment includes a case in which values including a minute error, a manufacturing error, or the like in a preset range are equivalent in addition to a case of “equal.” For example, when a plurality of values are included in a range of ±5% of an average value of the plurality of values, the plurality of values are defined as being equivalent.

The insulator 3 has a configuration in which a plurality of insulator layers are stacked. The insulator layers are formed of an organic insulating material such as polyimide. The insulator layers are stacked in the first direction D1. That is, the first direction D1 is a stacking direction. Actually, a plurality of insulator layers in the insulator 3 are unified to such an extent that boundaries between the layers are not visible.

The substrate 2 and the insulator 3 are provided as a unified body. The substrate 2 and the insulator 3 are arranged such that the principal face 2c and the principal face 3d face each other. A planarization layer 10 is disposed between the substrate 2 and the insulator 3. The planarization layer 10 is disposed between the principal face 2c of the substrate 2 and the principal face 3d of the insulator 3. Alumina, silicon oxide, or the like can be used for the planarization layer 10.

As illustrated in FIGS. 1 and 3, the first terminal electrode 4, the second terminal electrode 5, the third terminal electrode 6, the fourth terminal electrode 7, the fifth terminal electrode 8, and the sixth terminal electrode 9 are disposed on the principal face 3c of the insulator 3. The fourth terminal electrode 7 and the sixth terminal electrode 9 are input and output terminals. The first terminal electrode 4, the second terminal electrode 5, the third terminal electrode 6, and the fifth terminal electrode 8 are ground terminals.

The first terminal electrode 4, the second terminal electrode 5, the third terminal electrode 6, the fourth terminal electrode 7, the fifth terminal electrode 8, and the sixth terminal electrode 9 have a substantially rectangular parallelepiped shape in a plan view. The rectangular parallelepiped shape includes a shape in which corners and edges are chamfered and a shape in which corners and edges are rounded. The first terminal electrode 4, the third terminal electrode 6, the fourth terminal electrode 7, and the sixth terminal electrode 9 have a shape in which one corner is rounded (curved).

The first terminal electrode 4 is disposed at a position close to the end face 3a and close to the side face 3e. The second terminal electrode 5 is disposed at a position between the end face 3a and the end face 3b and close to the side face 3e. The third terminal electrode 6 is disposed at a position close to the end face 3b and close to the side face 3e. The fourth terminal electrode 7 is disposed at a position close to the end face 3a and close to the side face 3f. The fifth terminal electrode 8 is disposed at a position between the end face 3a and the end face 3b and close to the side face 3f. The sixth terminal electrode 9 is disposed at a position close to the end face 3b and close to the side face 3f.

The first terminal electrode 4, the second terminal electrode 5, and the third terminal electrode 6 are arranged with a predetermined a gap in the first direction D1. The fourth terminal electrode 7, the fifth terminal electrode 8, and the sixth terminal electrode 9 are arranged with a predetermined gap in the first direction D1. The first terminal electrode 4 and the fourth terminal electrode 7 are arranged with a predetermined gap in the third direction D3. The second terminal electrode 5 and the fifth terminal electrode 8 are arranged with a predetermined gap in the third direction D3. The third terminal electrode 6 and the sixth terminal electrode 9 are arranged with a predetermined gap in the third direction D3.

The first terminal electrode 4, the second terminal electrode 5, the third terminal electrode 6, the fourth terminal electrode 7, the fifth terminal electrode 8, and the sixth terminal electrode 9 may be formed of, for example, gold, nickel, copper, or silver.

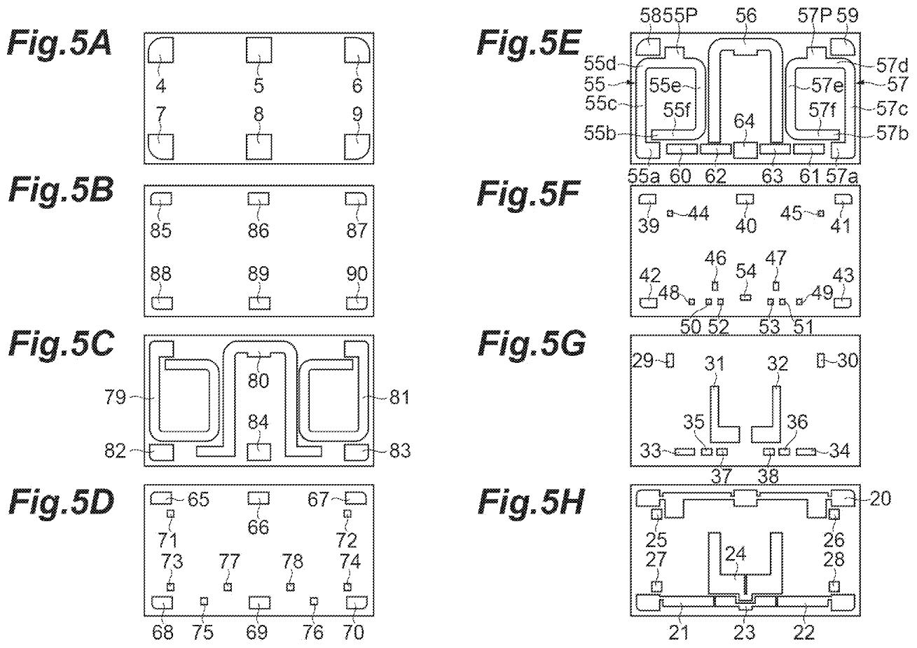

In the electronic component 1, an LC filter unit 11 is disposed in the insulator 3. FIGS. 5A, 5B, 5C, 5D, 5E, 5F, 5G, and 5H are diagrams illustrating conductor patterns constituting the LC filter unit 11. In the electronic component 1, conductor patterns are arranged in the order illustrated in FIGS. 5H, 5G, 5F, 5E, 5D, 5C, 5B, and 5A from the substrate 2 side (the principal face 3d side of the insulator 3). The conductor patterns include an inductor pattern, a capacitor pattern, and a through-hole pattern. The conductor patterns may be formed of, for example, copper.

As illustrated in FIG. 5H, the LC filter unit 11 includes a conductor pattern 20, a conductor pattern 21, a conductor pattern 22, a conductor pattern 23, a conductor pattern 24, a conductor pattern 25, a conductor pattern 26, a conductor pattern 27, and a conductor pattern 28. The conductor patterns 20 to 28 are arranged on the planarization layer 10.

As illustrated in FIG. 5G, the LC filter unit 11 includes a capacitor pattern (a first capacitor pattern) 29, a capacitor pattern (a third capacitor pattern) 30, capacitor pattern 31, a capacitor pattern 32, a capacitor pattern 33, a capacitor pattern 34, a capacitor pattern 35, a capacitor pattern 36, a capacitor pattern 37, and a capacitor pattern 38.

As illustrated in FIG. 5F, the LC filter unit 11 includes a through-hole pattern 39, a through-hole pattern 40, a through-hole pattern 41, a through-hole pattern 42, a through-hole pattern 43, a through-hole pattern 44, a through-hole pattern 45, a through-hole pattern 46, a through-hole pattern 47, a through-hole pattern 48, a through-hole pattern 49, a through-hole pattern 50, a through-hole pattern 51, a through-hole pattern 52, a through-hole pattern 53, and a through-hole pattern 54.

As illustrated in FIG. 5E, the LC filter unit 11 includes an inductor pattern (a first inductor pattern) 55, an inductor pattern (a second inductor pattern) 56, an inductor pattern (a third inductor pattern) 57, a conductor pattern 58, a conductor pattern 59, a conductor pattern 60, a conductor pattern 61, a conductor pattern 62, a conductor pattern 63, and a conductor pattern 64.

The inductor pattern 55 is disposed close to the end face 2a in the first direction D1. The inductor pattern 57 is disposed close to the end face 2b in the first direction D1. The inductor pattern 56 is disposed between the inductor pattern 55 and the inductor pattern 57 in the first direction D1. The inductor pattern 55, the inductor pattern 56, and the inductor pattern 57 are arranged in parallel in the first direction D1 when seen in the second direction D2.

As illustrated in FIG. 5D, the LC filter unit 11 includes a through-hole pattern 65, a through-hole pattern 66, a through-hole pattern 67, a through-hole pattern 68, a through-hole pattern 69, a through-hole pattern 70, a through-hole pattern 71, a through-hole pattern 72, a through-hole pattern 73, a through-hole pattern 74, a through-hole pattern 75, a through-hole pattern 76, a through-hole pattern 77, and a through-hole pattern 78.

As illustrated in FIG. 5C, the LC filter unit 11 includes an inductor pattern 79, an inductor pattern 80, an inductor pattern 81, a conductor pattern 82, a conductor pattern 83, and a conductor pattern 84.

The inductor pattern 79 is disposed close to the end face 2a in the first direction D1. The inductor pattern 81 is disposed close to the end face 2b in the first direction D1. The inductor pattern 80 is disposed between the inductor pattern 79 and the inductor pattern 81 in the first direction D1. The inductor pattern 79, the inductor pattern 80, and the inductor pattern 81 are arranged in parallel in the first direction D1 when seen in the second direction D2.

As illustrated in FIG. 5B, the LC filter unit 11 includes a through-hole pattern 85, a through-hole pattern 86, a through-hole pattern 87, a through-hole pattern 88, a through-hole pattern 89, and a through-hole pattern 90.

As illustrated in FIG. 5A, the electronic component 1 includes the first terminal electrode 4, the second terminal electrode 5, the third terminal electrode 6, the fourth terminal electrode 7, the fifth terminal electrode 8, and the sixth terminal electrode 9.

As illustrated in FIG. 5E, the inductor pattern 55 includes one end 55a and the other end 55b. The inductor pattern 55 includes a first pattern portion 55c extending in the third direction D3, a second pattern portion 55d connected to an end of the first pattern portion 55c (an end opposite to the one end 55a) and extending in the first direction D1, a third pattern portion 55e connected to an end of the second pattern portion 55d and extending in the third direction D3, and a fourth pattern portion 55f connected to an end of the third pattern portion 55e and extending in the first direction D1.

The first pattern portion 55c is connected close to the end face 3a. The first pattern portion 55c and the third pattern portion 55e are separated in the first direction D1. The second pattern portion 55d and the fourth pattern portion 55f are separated in the third direction D3.

A pad (a first connection portion) 55P is provided in the inductor pattern 55. In the inductor pattern 55, the pad 55P is provided between one end 55a and the other end 55b of the inductor pattern 55. The pad 55P can also be said to be provided in the middle of a path between the one end 55a and the other end 55b of the inductor pattern 55. Specifically, the pad 55P is provided in the second pattern portion 55d. The pad 55P protrudes from the second pattern portion 55d toward the side face 3e. The pad 55P is located in an area between the first terminal electrode 4 and the second terminal electrode 5 when seen in the second direction D2.

The pad 55P is connected to the capacitor pattern 29 via the through-hole pattern 44. That is, the inductor pattern 55 and the capacitor pattern 29 are electrically connected between the one end 55a and the other end 55b of the inductor pattern 55.

The inductor pattern 57 includes one end 57a and the other end 57b. The inductor pattern 57 includes a first pattern portion 57c extending in the third direction D3, a second pattern portion 57d connected to an end of the first pattern portion 57c (an end opposite to the one end 57a) and extending in the first direction D1, a third pattern portion 57e connected to an end of the second pattern portion 57d and extending in the third direction D3, and a fourth pattern portion 57f connected to an end of the third pattern portion 57e and extending in the first direction D1.

The first pattern portion 57c is connected close to the end face 3b. The first pattern portion 57c and the third pattern portion 57e are separated in the first direction D1. The second pattern portion 57d and the fourth pattern portion 57f are separated in the third direction D3.

A pad (a third connection portion) 57P is provided in the inductor pattern 57. In the inductor pattern 57, the pad 57P is provided between one end 57a and the other end 57b of the inductor pattern 57. The pad 57P can also be said to be provided in the middle of a path between the one end 57a and the other end 57b of the inductor pattern 57. Specifically, the pad 57P is provided in the second pattern portion 57d. The pad 57P protrudes from the second pattern portion 57d toward the side face 3e. The pad 57P is located in an area between the second terminal electrode 5 and the third terminal electrode 6 when seen in the second direction D2.

The pad 57P is connected to the capacitor pattern 30 via the through-hole pattern 45. That is, the inductor pattern 57 and the capacitor pattern 30 are electrically connected between the one end 57a and the other end 57b of the inductor pattern 57.

The through-hole pattern 39 connects the conductor pattern 20 and the conductor pattern 58. The through-hole pattern 40 connects the conductor pattern 20 and the inductor pattern 56. The through-hole pattern 41 connects the conductor pattern 20 and the conductor pattern 59. The through-hole pattern 42 connects the conductor pattern 21 and the inductor pattern 55. The through-hole pattern 43 connects the conductor pattern 22 and the inductor pattern 57. The through-hole pattern 44 connects the capacitor pattern 29 and the pad 55P of the inductor pattern 55. The through-hole pattern 45 connects the capacitor pattern 30 and the pad 57P of the inductor pattern 57.

The through-hole pattern 46 connects the capacitor pattern 31 and the inductor pattern 56. The through-hole pattern 47 connects the capacitor pattern 32 and the inductor pattern 56. The through-hole pattern 48 connects the capacitor pattern 33 and the conductor pattern 60. The through-hole pattern 49 connects the capacitor pattern 34 and the conductor pattern 61. The through-hole pattern 50 connects the capacitor pattern 35 and the conductor pattern 62. The through-hole pattern 51 connects the capacitor pattern 36 and the conductor pattern 63. The through-hole pattern 52 connects the capacitor pattern 37 and the conductor pattern 62. The through-hole pattern 53 connects the capacitor pattern 38 and the conductor pattern 63. The through-hole pattern 54 connects the conductor pattern 24 and the conductor pattern 64.

The through-hole pattern 65 connects the conductor pattern 58 and the inductor pattern 79. The through-hole pattern 66 connects the inductor pattern 56 and the inductor pattern 80. The through-hole pattern 67 connects the conductor pattern 59 and the inductor pattern 81. The through-hole pattern 68 connects the inductor pattern 55 and the conductor pattern 82. The through-hole pattern 69 connects the conductor pattern 64 and the conductor pattern 84. The through-hole pattern 70 connects the inductor pattern 57 and the conductor pattern 83. The through-hole pattern 71 connects the inductor pattern 55 and the inductor pattern 79.

The through-hole pattern 72 connects the inductor pattern 57 and the inductor pattern 81. The through-hole pattern 73 connects the inductor pattern 55 and the inductor pattern 79. The through-hole pattern 74 connects the inductor pattern 57 and the inductor pattern 81. The through-hole pattern 75 connects the conductor pattern 60 and the inductor pattern 80. The through-hole pattern 76 connects the conductor pattern 61 and the inductor pattern 80. The through-hole pattern 77 connects the inductor pattern 56 and the inductor pattern 80. The through-hole pattern 78 connects the inductor pattern 56 and the inductor pattern 80.

The through-hole pattern 85 connects the inductor pattern 79 and the first terminal electrode 4. The through-hole pattern 86 connects the inductor pattern 80 and the second terminal electrode 5. The through-hole pattern 87 connects the inductor pattern 81 and the third terminal electrode 6. The through-hole pattern 88 connects the conductor pattern 82 and the fourth terminal electrode 7. The through-hole pattern 89 connects the conductor pattern 84 and the fifth terminal electrode 8. The through-hole pattern 90 connects the conductor pattern 83 and the sixth terminal electrode 9.

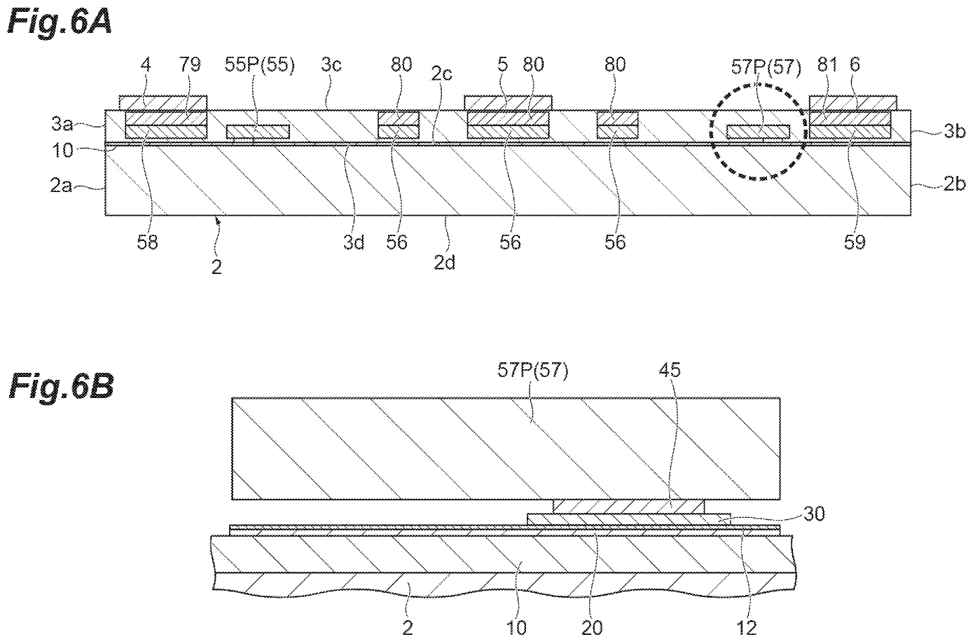

FIG. 6A is a sectional view taken along line VI-VI in FIG. 2 and FIG. 6B is a partially enlarged view of FIG. 6A. As illustrated in FIG. 6B, a dielectric layer 12 is disposed between the conductor pattern 20 and the capacitor pattern 30. The dielectric layer 12 is also disposed between the conductor patterns 20 to 24 and the capacitor patterns 29 and 31 to 38. The dielectric layer 12 may be formed of, for example, an inorganic insulating material including a paraelectric material or a ferroelectric material such as silicon nitride or silicon oxide.

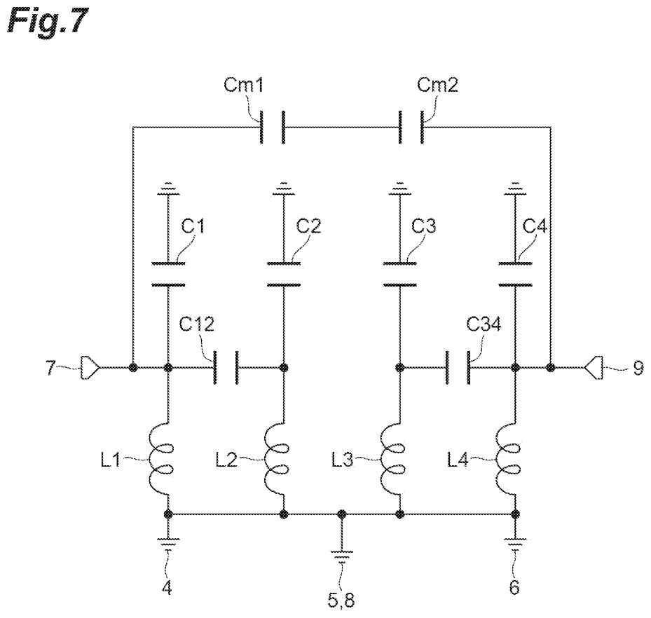

As illustrated in FIG. 7, the electronic component 1 includes a first inductor L1, a second inductor L2, a third inductor L3, a fourth inductor L4, a first capacitor C1, a second capacitor C2, a third capacitor C3, a fourth capacitor C4, a fifth capacitor C12, a sixth capacitor C34, a seventh capacitor Cm1, and an eighth capacitor Cm2.

The first inductor L1 includes the inductor pattern 55 and the inductor pattern 79. The second inductor L2 includes the inductor pattern 56 and the inductor pattern 80. The third inductor L3 includes the inductor pattern 56 and the inductor pattern 80. The fourth inductor L4 includes the inductor pattern 57 and the inductor pattern 81.

The first capacitor C1 is formed by the conductor pattern 20 and the capacitor pattern 29. The second capacitor C2 is formed by the conductor pattern 24 and the capacitor pattern 31. The third capacitor C3 is formed by the conductor pattern 24 and the capacitor pattern 32. The fourth capacitor C4 is formed by the conductor pattern 20 and the capacitor pattern 30.

The fifth capacitor C12 is formed by the conductor pattern 21 and the capacitor pattern 33. The sixth capacitor C34 is formed by the conductor pattern 22 and the capacitor pattern 34. The seventh capacitor Cm1 is formed by the conductor patterns 21 and 23 and the capacitor patterns 35 and 37. The eighth capacitor Cm2 is formed by the conductor patterns 22 and 23 and the capacitor patterns 36 and 38.

The first inductor L1 and the first capacitor C1 form a first LC resonator. The second inductor L2 and the second capacitor C2 form a second LC resonator. The third inductor L3 and the third capacitor C3 form a third LC resonator. The fourth inductor L4 and the fourth capacitor C4 form a fourth LC resonator.

As described above, in the electronic component 1 according to this embodiment, the inductor pattern 55 and the capacitor pattern 29 are electrically connected between one end 55a and the other end 55b of the inductor pattern 55. In this way, in the electronic component 1, the one end 55a or the other end 55b of the inductor pattern 55 and the capacitor pattern 29 are not electrically connected, but the inductor pattern 55 and the capacitor pattern 29 are electrically connected at a position between the one end 55a and the other end 55b of the inductor pattern 55. Accordingly, in the electronic component 1, arrangement of the capacitor pattern 29 is not restricted in a relationship with a position of the one end 55a or the other end 55b of the inductor pattern 55. As a result, it is possible to achieve improvement in a degree of freedom in design associated with arrangement of the capacitor patterns in the electronic component 1.

In the electronic component 1 according to this embodiment, the pad 55P is provided between the one end 55a and the other end 55b of the inductor pattern 55. The pad 55P is electrically connected to the capacitor pattern 29. With this configuration, arrangement of the capacitor pattern 29 can be changed by changing the position of the pad 55P. Accordingly, it is possible to achieve improvement in a degree of freedom in design associated with arrangement of capacitor patterns.

In the electronic component 1 according to this embodiment, the insulator 3 includes the inductor pattern 56. The inductor pattern 55 and the inductor pattern 56 are arranged in parallel in the first direction D1 when seen in the second direction D2. In this way, in the configuration in which a plurality of inductor patterns 55 and 56 are arranged in parallel, the arrangement of the capacitor patterns may be restricted. Particularly, when it is intended to decrease the size of the electronic component 1, a space for arrangement of the capacitor patterns is restricted and thus a degree of freedom in arrangement of the capacitor patterns decreases. Accordingly, the configuration in which the pad 55P and the capacitor pattern 29 are connected is useful for the configuration in which a plurality of inductor patterns 55 and 56 are arranged in parallel.

In the electronic component 1 according to this embodiment, the first terminal electrode 4 and the fourth terminal electrode 7 are arranged separately in the third direction D3 when seen in the second direction D2. The pad 55P of the inductor pattern 55 is arranged outside of an area between the first terminal electrode 4 and the fourth terminal electrode 7 arranged separately in the third direction D3. In the configuration in which the inductor pattern 55 and the inductor pattern 56 are arranged in parallel in the first direction D1, when the pad 55P is arranged in an area between the first terminal electrode 4 and the fourth terminal electrode 7 arranged separately in the third direction D3, a diameter of the inductor pattern 55 decreases and desired characteristics are hard to obtain. Therefore, it is possible to secure the diameter of the inductor pattern 55 by arranging the pad 55P outside of the area between the first terminal electrode 4 and the fourth terminal electrode 7 arranged separately in the third direction D3.

In the electronic component 1 according to this embodiment, the pad 55P is located in an area between the first terminal electrode 4 and the second terminal electrode 5 when seen in the second direction D2. Accordingly, in the electronic component 1, since the first pattern portion 55c of the inductor pattern 55 can be arranged between the first terminal electrode 4 and the fourth terminal electrode 7, it is possible to secure the diameter of the inductor pattern 55. In the electronic component 1, the area between the first terminal electrode 4 and the second terminal electrode 5 in which the pad 55P is arranged is a dead space. Accordingly, by utilizing such a dead space, it is possible to achieve a decrease in size of the electronic component 1 while securing characteristics of the electronic component 1.

The electronic component 1 according to this embodiment includes the inductor pattern 57 and the capacitor pattern 30. In the electronic component 1, the inductor pattern 55, the inductor pattern 56, and the inductor pattern 57 are arranged in parallel in the first direction D1 when seen in the second direction D2. In the inductor pattern 57, the pad 57P is provided between the one end 57a and the other end 57b, and the pad 57P is electrically connected to the capacitor pattern 30. In this way, in the configuration in which a plurality of inductor patterns 55, 56, and 57 are arranged in parallel, arrangement of the capacitor patterns may be restricted. Particularly, when it is intended to decrease the size of the electronic component 1, a space for arrangement of the capacitor patterns is restricted and thus a degree of freedom in arrangement of the capacitor patterns decreases. Accordingly, the configuration in which the pad 55P and the capacitor pattern 29 are connected and the pad 57P and the capacitor pattern 30 are connected is useful for the configuration in which a plurality of inductor patterns 55, 56, and 57 are arranged in parallel.

While an embodiment of the present disclosure has been described above, the present disclosure is not limited to the embodiment and can be modified in various forms without departing from the gist thereof.

In the aforementioned embodiment, an example in which the LC filter unit 11 includes the inductor pattern 55, the inductor pattern 56, and the inductor pattern 57 is described. However, the LC filter unit has only to include at least the inductor pattern 55.

In the aforementioned embodiment, an example in which the pad 55P is provided in the second pattern portion 55d and protrudes from the second pattern portion 55d toward the side face 3e is described. However, the position at which the pad is provided is not limited thereto. The pad 55P may be disposed at a different position. The same is true of the pad 57P.

In the aforementioned embodiment, an example in which the pad 55P is provided in the inductor pattern 55 is described. However, the pad 55P may not be provided in the inductor pattern 55. In this case, the inductor pattern 55 and the capacitor pattern 29 have only to be electrically connected between the one end 55a and the other end 55b of the inductor pattern 55. The same is true of the inductor pattern 57.

What is claimed is:

1. An electronic component comprising:
an element assembly; and
a first inductor pattern and a first capacitor pattern arranged in the element assembly,
wherein the first inductor pattern and the first capacitor pattern are electrically connected between one end and the other end of the first inductor pattern.

2. The electronic component according to claim 1, wherein a first connection portion is provided between the one end and the other end of the first inductor pattern, and
wherein the first connection portion is electrically connected to the first capacitor pattern.

3. The electronic component according to claim 2, wherein the element assembly includes a pair of end faces facing each other in a first direction, a pair of principal faces facing each other in a second direction, and a pair of side faces facing each other in a third direction,
wherein the electronic component further comprises a second inductor pattern arranged in the element assembly, and
wherein the first inductor pattern and the second inductor pattern are arranged in parallel in the first direction when seen in the second direction.

4. The electronic component according to claim 3, further comprising a plurality of terminal electrodes arranged in the element assembly,
wherein two terminal electrodes out of the plurality of terminal electrodes are arranged separately in the third direction when seen in the second direction, and
wherein the first connection portion is arranged outside of an area between the two terminal electrodes arranged separately in the third direction.

5. The electronic component according to claim 3, further comprising a third inductor pattern and a third capacitor pattern,
wherein the first inductor pattern, the second inductor pattern, and the third inductor pattern are arranged in parallel in the first direction when seen in the second direction,
wherein a third connection portion is provided between one end and the other end of the third inductor pattern, and
wherein the third connection portion is electrically connected to the third capacitor pattern.
